(19) United States
(12) Patent Application Publication
(10) Pub. No.: US 2013/0292168 A1
(43) Pub. Date: Nov. 7, 2013

(54) STARTING MATERIAL FOR A SINTERED BOND AND PROCESS FOR PRODUCING THE SINTERED BOND

(71) Applicants: Daniel Wolde-Giorgis, Filderstadt (DE); Andrea Feiock, Pliezhausen (DE)

(72) Inventors: Daniel Wolde-Giorgis, Filderstadt (DE); Andrea Feiock, Pliezhausen (DE)

(73) Assignee: ROBERT BOSCH GMBH, Stuttgart (DE)

(21) Appl. No.: 13/880,975

(22) PCT Filed: Sep. 23, 2011
(86) PCT No.: PCT/EP2011/066613

§ 371 Date: Jul. 8, 2013

(30) Foreign Application Priority Data
Oct. 20, 2010 (DE) 10 2010 042 702.0

(51) Int. Cl. H05K 13/04; B23K 35/34; H05K 1/11

(52) U.S. Cl. CPC H05K 13/0465; H05K 1/11; B23K 35/34
USPC 174/261; 148/24; 228/198; 403/270

(57) ABSTRACT

The invention relates to a starter material for a sintering compound, said starter material comprising particles which at least proportionally contain an organic metal compound and/or a precious metal oxide, the organic metal compound and/or the precious metal oxide being converted during heat treatment of the starter material into the elemental metal and/or precious metal. The invention is characterized in that the particles have a coating containing a reducing agent by means of which the organic metal compound and/or precious metal oxide is reduced to the elemental metal and/or precious metal at a temperature below the sintering temperature of the elemental metal and/or precious metal.

### BACKGROUND OF THE INVENTION

The invention relates to a sintered bond, a starting material for this and a process for producing it, and also an electronic circuit containing the sintered bond.

Power electronics are used in many fields of technology. Especially in electrical or electronic appliances in which large currents flow, the use of power electronics is indispensable. The currents necessary in power electronics lead to thermal stressing of the electrical or electronic components present therein. Further thermal stress is caused by the use of such electrical or electronic appliances in places of operation having a temperature which is significantly above room temperature. Examples which may be mentioned are control instruments in the automobile sector which are arranged directly in the engine compartment. Here, the control instrument is additionally subjected to continual changes in temperature, as a result of which the electrical and/or electronic components therein are subjected to great thermal stresses. In general, temperature changes in the range up to a temperature of 200 degrees Celsius are usual. However, use temperatures going beyond this are also increasingly required. This leads to overall increased demands being placed on the reliability and the functional reliability of electrical or electronic instruments having power electronics.

Joining of electrical or electronic components, for example to a support substrate, is usually effected by means of a bonding layer. Known examples of such a bonding layer are solder bonds, for example composed of tin-silver or tin-silver-copper. At relatively high use temperatures, lead-containing solder bonds can be used. However, lead-containing solder bonds are greatly restricted in respect of their permissible industrial applications by legal obligations for reasons of environmental protection. An alternative for use at elevated or high temperatures, in particular above 200 degrees Celsius, are lead-free hard solders. Lead-free hard solders generally have a melting point above 200° C. A problem is that when hard solder is used for forming a bonding layer, only few electrical or electronic components are possible as join partners which can withstand the high temperatures during melting of the hard solders.

Use is also made of sintered bonds which can be processed at low temperatures and are nevertheless suitable for operation at elevated temperatures. Thus, the patent application DE102007046901 A1 discloses such sintered bonds. To produce a sintered bond, a paste-like starting material comprising readily decomposable silver compounds and also silver flocs or nanosilver is used. Furthermore, copper, for example, can be present in the starting material. To form the paste, solvents are mixed in. When the starting material is thermally treated at below 300° C., the silver compounds decompose to form elemental silver and together with the silver flocs and the nanosilver form the sintered bond. The sintered bond is used for contacting two elements. Contacting can be effected at low contact pressures of the contact partners when using the starting material described.

DE 60221433 T2 discloses a sintered bond which is produced from a paste containing particles of a silver compound. Apart from the particles of the silver compound, a reducing agent is also present in dissolved form. In the thermal treatment of the silver paste below 200° C., the silver compound is reduced to elemental silver to form the sintered bond.

U.S. Pat. No. 6,951,666 discloses the production of various sintered bonds. Here, general possible combinations of various starting elements are described. Starting elements mentioned are, inter alia, molecular metals, numerous metallic particles in the nanometer or micron size range, coatings, solvents, additives, reducing agents, crystallization inhibitors, wetting agents and more.

### SUMMARY OF THE INVENTION

Advantages

It is an object of the invention to provide a starting material for a sintered bond, by means of which a sintered bond can be produced in a simple way at low processing temperatures and pressures.

This object is achieved by a sintered bond, a starting material for this and a process for producing it, and also by an electronic circuit containing the sintered bond.

The starting material of the invention for a sintered bond comprises particles which contain at least a proportion of an organic metal compound and/or or a noble metal oxide, where the organic metal compound and/or the noble metal oxide are converted in a thermal treatment of the starting material into the parent elemental metal and/or noble metal. The invention is characterized in that the particles have a coating containing a reducing agent by means of which the organic metal compound and/or the noble metal oxide are reduced to the elemental metal and/or noble metal at a temperature below the sintering temperature of the elemental metal and/or noble metal. The coating provided according to the invention advantageously encloses the particles completely, but at least virtually completely. As a result, the coating acts as a protective shell by means of which it can be ensured that the particles, in particular the proportion of metal compounds and/or noble metal oxides in the particles, remain chemically unchanged. The particles or the starting material comprising the particles can thus be stored until production of a sintered bond.

As a result of the presence of a reducing agent in a coating of the particles, the reducing agent is positioned as reducing partner as close as possible to the particles, in particular also to the proportion of organic metal compound and/or noble metal oxide therein. The reduction process therefore proceeds in a particularly optimized manner. Firstly, very rapid conversion of the organic metal compound and/or the noble metal oxide into the parent elemental metal or noble metal results. Secondly, the reducing agent is distributed very uniformly and finely by application as a coating. This applies both to the distribution of the reducing agent on a particle itself and also to the starting material containing the particles. The reduction process thus proceeds simultaneously and uniformly over all particles. This results in the advantage that a sintered bond produced from the starting material of the invention has a very homogeneous sintered microstructure.

Furthermore, it is particularly advantageous that this additionally produces conditions which, when a sufficient amount of reducing agent is present, lead to conversion of virtually all, preferably all, of the organic metal compound and/or noble metal oxide present in the starting material to the elemental metal or noble metal. A particularly high thermal and/or electrical conductivity of the sintered bonds produced from the starting material of the invention is then advantageously obtained.

In a first embodiment, the particles in the starting material of the invention preferably consist either entirely of the organic metal compound or entirely of the noble metal oxide. As an alternative, the starting material is provided as a mixture of particles of an organic metal compound and particles of a noble metal oxide. In addition, the particles provided in the starting material which consist of an organic metal compound can differ from one another in that at least two different organic metal compounds are provided for these. The same also applies to the particles provided in the starting material which consist of a noble metal oxide: particles comprising a first noble metal oxide and particles comprising at least one second noble metal oxide are then provided.

Finally, particles which contain both a proportion of an organic metal compound and a proportion of a noble metal oxide can also be provided according to the invention. Such particles can be produced, for example, by pressing or milling of starting particles composed of an organic metal compound and starting particles composed of a noble metal oxide. There are further chemical or physical possibilities for producing such particles; these can be found in the technical literature on particle production. Overall, it is advantageous for the particles provided for the starting material to be able to be procured as widely marketed standard particles and thus to be very inexpensive.

In a further embodiment, the particles of the starting material comprise a metallic core which is provided with an outer layer. Here, the outer layer is configured as a coating composed of an organic metal compound and/or a noble metal oxide on the metallic core. In a preferred embodiment, the coating composed of the organic metal compound or noble metal oxide has the same metallic basis as the metallic core. However, it is likewise conceivable for the metallic basis of the coating composed of organic metal compound or noble metal oxide to differ from the material of the metallic core. A further advantageous possibility is to use different variants of these particles in the starting material. The variants are obtained in respect of different metallic cores and/or in respect of different coatings applied to the metallic cores. Thus, for example, particles having a core composed of a first metal and particles having a core of at least one second metal can be present in the starting material. Furthermore, particles having a metallic core and a coating composed of a first organic metal compound and/or a first noble metal oxide applied to this core and particles having a metallic core and a coating composed of at least one second organic metal compound and/or a second noble metal oxide applied to this core can also be provided.

In this embodiment, the metallic core of the particles is preferably made of copper or a noble metal. Particular preference is given to a metallic core composed of silver, gold, platinum and/or palladium. Furthermore, such a particle core is preferably provided with a coating composed of silver or silver oxide. Such coatings composed of silver or silver oxide make it easier to apply a further coating containing a reducing agent, e.g. a fatty acid. As an alternative, such a particle core made of silver can also be provided with a coating composed of sodium carbonate which in turn is provided with a further coating containing a reducing agent. In this case, a silver-sodium alloy is formed in a thermal treatment of the starting material. This alloy has a melting point lower than that of silver. This aids adhesive contact of all particles present in the starting material, and diffusion processes proceeding during the sintering process are promoted.

In this embodiment of the particles having a metallic core, the metallic core preferably takes up a large proportion of the volume, while the coating having, in particular, a low coating layer thickness makes up a comparatively small proportion of the particles. The coating composed of the organic metal compound and/or the noble metal oxide advantageously encapsulates the metallic core. This ensures that the metallic core is protected against chemical reaction processes. Thus, the particles, in particular the metallic core of the particles, in the starting material remain chemically stable until formation of a sintered bond under the action of heat.

Furthermore, it is particularly advantageous that the reduction process occurring in a thermal treatment, in which the organic metal compound and/or the noble metal oxide are reduced to the parent elemental metal and/or noble metal, proceeds particularly quickly in this embodiment of the particles having a metallic core. This is due to the fact that the reduction process is restricted to the coating composed of an organic metal compound or noble metal oxides applied to the metallic core. The low layer thickness of the coating additionally ensures that the total amount of organic metal compound and/or noble metal oxide present in the starting material is converted into the elemental metal and/or the noble metal oxide. Furthermore, only small amounts of gaseous by-products are formed as a result of the reduction process in this embodiment.

The particles in the embodiments described up to now preferably contain a silver carbonate, a silver lactate, a silver stearate or a sodium carbonate as organic metal compound. If at least a proportion of noble metal oxide is provided in the particles, this is preferably a silver oxide. In principle, the abovementioned preferred organic metal compounds and the preferred noble metal oxide are then reduced to silver as the metal on which the particles are based in a thermal treatment of the starting material. As a result, the sintered bond formed in this way from the starting material has a particularly high thermal and/or electrical conductivity.

In a further embodiment of the invention, the coating containing a reducing agent which is applied to the particles advantageously comprises at least one organic material as reducing agent. Particular preference is given to using reducing agents which contain at least one alcohol from the group consisting of primary and secondary alcohols and/or an amine and/or formic acid. Furthermore, it is particularly advantageous for the reducing agent to contain a fatty acid, in particular an isostearic acid, a stearic acid, an oleic acid, a lauric acid, or a mixture of various fatty acids. The coating provided according to the invention which contains a reducing agent can also be formed exclusively by the reducing agent itself, in particular by the abovementioned reducing agents.

Overall, such coatings can be applied in a simple way to the particles provided for the starting material. In addition, the reducing agents mentioned display a particularly good reducing action in respect of the organic metal compounds or noble metal oxides present in at least a proportion in the organic starting material during a thermal treatment of the starting material to form a sintered bond.

Basically, the organic metal compounds or noble metal oxides are converted at high temperatures into the parent elemental metal or noble metal. When using a coating containing a reducing agent, the conversion of the organic metal compound and/or the noble metal oxide into the elemental metal and/or noble metal advantageously occurs at low processing temperatures. In particular, the elemental metal and/or noble metal is formed in a thermal treatment of the starting material below the sintering temperature of the elemental metal and/or noble metal. This advantageously makes it possible for the join partners joined by the sintered bond formed, for example electrical and/or electronic components of an electronic circuit, not to be subjected to high temperatures during the formation of the sintered bond. Thus, heat-sensitive electrical and/or electronic components in electronic circuits, which have not been able to be used because of the otherwise usual excessively high process temperatures in production of the bond, can be electrically and/or thermally contacted.

Overall, the starting material of the invention displays, as a result of the measures in the embodiments and developments mentioned, a very high degree of conversion of up to 99% and more of the organic metal compounds and/or noble metal oxides present into the elemental metal and/or noble metal. An at least virtually complete conversion can, in particular, be achieved when the proportion of organic metal compound and/or noble metal oxide is in an essentially stoichiometric ratio to the proportion of the reducing agent in the coating containing a reducing agent. Amounts which have not been converted, which can otherwise remain in the sintered bond because of an insufficient amount of reducing agent, can reduce the thermal conductivity of the sintered bond.

Since, owing to the stoichiometric ratio, an excess of reducing agent is ruled out, the formation of a sintered bond from the starting material can alternatively be carried out under reduced pressure or in a protective gas atmosphere. If, on the other hand, an excess of reducing agent is present, it is necessary to supply oxygen, e.g. in the form of air, in order to burn out the reducing agent completely.

In a further embodiment of the starting material of the invention, further particles containing an element of the fourth main group of the Periodic Table are advantageously additionally provided. These further particles can contribute to setting advantageous properties of the sintered bond formed from the starting material.

A first possibility is preferably to mix further particles composed of silicon into the starting material. Silicon is added, for example, as filler to the starting material, as a result of which the coefficient of thermal expansion of a sintered bond formed from the starting material is reduced. In addition, silicon has a high electrical conductivity. Particles composed of silicon are also added to the starting material as inexpensive alternatives to silver or to silver compounds. In this way, the proportion of silver in the starting material can be kept low. Fundamentally, particles composed of silicon are advantageously inert during a thermal treatment of the starting material to form a sintered bond. Thus, particles composed of silicon are present in unchanged form within a matrix of the conversion products composed of metal and/or noble metal in a sintered bond formed.

Another possibility is, likewise preferably, to add further particles composed of tin and lead to the starting material. In a thermal treatment of the starting material, tin and lead form alloys with the conversion products composed of metal and/or noble metal which are formed as a result of the reduction process which takes place. These alloys have a melting point lower than that of the metal and/or noble metal, as a result of which the processing temperature to form the sintered bond can be reduced further. In addition, the alloys are then present as ductile phases within the sintered microstructure formed, as a result of which the sintered bonds formed are less susceptible to thermal and/or mechanical stresses, in particular changing stresses. Furthermore, tin, for example, has a low melting point, so that the particles of tin melt at an early juncture in a thermal treatment of the starting material and bring about adhesive contact of all particles present in the starting material. This advantageously promotes the diffusion processes proceeding during the sintering process.

An additional possibility is, likewise preferably, to make the further particles of a noble metal, for example silver. These intrinsically have a high thermal and/or electrical conductivity.

In a further embodiment of the invention, the further particles additionally have a coating. A coating, for example of a noble metal, brings about an overall improvement in the sintering of the further particles within the sintered microstructure of a sintered bond formed from the starting material. Thus, for example, further particles composed of silicon are preferably coated with silver and/or gold. In the case of further particles composed of a noble metal, these are preferably provided with an additional coating which contains a reducing agent, in particular a fatty acid. Further particles composed of a noble metal, in particular silver, which are coated in this way additionally promote the reduction of the organic metal compound and/or noble metal oxide of which at least some is present in the starting material to the elemental metal and/or noble metal.

It is in principle advantageous for the particles present in the starting material to have an average particle size of 0.01-50 μm, particularly preferably 0.1-10 μm. As a result of the relatively large specific surface area, these particles have an increased reactivity. In this way, the processing temperature and processing time necessary to form a sintered bond can be kept low.

Furthermore, the particles are preferably spherical and/or platelet-like. A mixture of such particle geometries, optionally together with round particles, makes it possible to achieve a high density of the sintered bond formed from the starting material.

The starting material is preferably provided as a paste. The viscosity of the paste can be set mainly by means of the solvent added. It is likewise advantageous to provide the starting material in the form of a pellet or as a shaped body, in particular as a flat shaped body. In this case, the paste-like starting material is introduced into a mold or applied to a film. The solvent is subsequently driven off from the starting material by means of a thermal treatment. Here, a solvent which can be driven off without leaving a residue at a temperature below the actual sintering temperature of the starting material should be provided. The starting material formed in this way can also be manufactured in the form of a large sheet which is then cut into small shaped bodies for the particular application.

The coating on particles present in the starting material can in principle be applied by means of known coating processes. These may be found in the known technical literature. Examples which may be mentioned are chemical and physical coating processes such as chemical or physical vapor deposition.

Experiments to date show that the sintered bond formed from the starting material of the invention can attain the electrical conductivity of pure silver, but has at least an electrical conductivity which is only slightly below that of pure silver. In addition, the sintered bond formed has a thermal conductivity of >100 W/mK.

The invention further provides a process for forming a thermally and/or electrically conductive sintered bond. Here, a starting material of the above-described type is used and is introduced between two join partners. Preferred join partners are electrical and/or electronic components having contact points which are brought into direct physical contact with the starting material. Here, the starting material can be applied in the form of a printing paste, for example by means of screen printing or stenciling. Application by ink jet or dispensing processes is likewise possible. A further very simple possibility is to arrange the starting material as shaped body between the join partners.

The sintered bond is subsequently formed by thermal treatment of the starting material. When heat is supplied, the organic metal compound or the noble metal oxide of which at least some is present in the starting material reacts with the reducing agent present in the coating. This is a reduction process in which the organic metal compound and/or the noble metal oxide are/is reduced to the parent elemental metal and/or noble metal.

The reduction process advantageously commences at below the sintering temperature of the elemental metal and/or noble metal. A processing temperature of <400° C., preferably <300° C., in particular <250° C., is therefore provided. To improve the sintering process, this is optionally carried out under pressure. A pressure of <4 MPa, preferably <1.6 MPa, particularly preferably <0.8 MPa, is employed as process pressure. Excess reducing agent is completely burnt out providing sufficient oxygen is supplied, for example under an air atmosphere. Join partners are preferably provided with contact points composed of a noble metal, for example gold, silver or an alloy of gold or silver.

In an alternative variant of the process of the invention, the sintered bond is formed under reduced pressure and/or under a nitrogen atmosphere. Since excess reducing agent cannot be burnt out in this case, a starting material in which the organic metal compound and/or noble metal oxide is present in a stoichiometric ratio to the reducing agent present in the coating containing a reducing agent should be provided. During the thermal treatment, the reducing agent present is accordingly completely consumed. In addition, the organic metal compound and/or the noble metal oxide are completely converted into the elemental metal and/or noble metal. In this process variant, join partners having a contact point which does not contain noble metal and is instead composed, for example, of copper can advantageously also be provided. This enables inexpensive electrical and/or electronic components also to be employed. Furthermore, dispensing with a process pressure which is otherwise necessary means that the electrical and/or electronic components provided are not subjected to mechanical stresses.

### BRIEF DESCRIPTION OF THE DRAWINGS

Further advantages, features and details of the invention may be derived from the following description of preferred illustrative embodiments and with the aid of the drawings. In the drawings:

FIG. 1a schematically shows particles of a starting material according to the invention for a sintered bond according to a first embodiment,

FIG. 1b schematically shows an alternative embodiment of particles of a starting material according to the invention for a sintered bond according to a second embodiment,

FIG. 2a schematically shows a mixture of particles in a starting material according to the invention having particles corresponding to FIG. 1a and particles composed of silicon,

FIG. 2b schematically shows an alternative mixture of particles corresponding to FIG. 1a and particles composed of tin,

FIG. 2c schematically shows a further mixture of particles of a starting material according to the invention having particles corresponding to FIG. 1b and further particles composed of silver,

FIG. 3 schematically shows a sectional view of a sintering oven and an electronic circuit arranged in the sintering oven, where the electronic circuit has a starting material according to the invention between a chip and a substrate.

### DETAILED DESCRIPTION

In the figures, identical components and components having the same function are characterized by the same reference numerals.

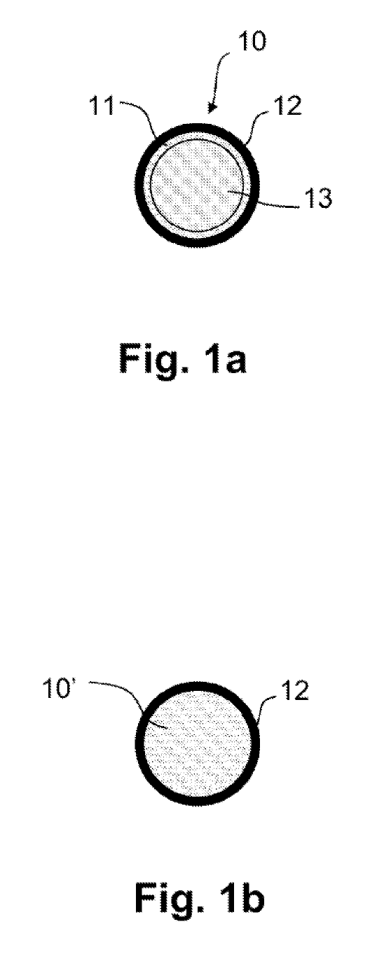

FIG. 1a schematically shows particles 10 which are provided in a starting material according to the invention for a sintered bond in a first embodiment. The particles 10 have a metallic core 13 which is composed of silver and on which a thin first coating 11 which preferably completely encloses the metallic core has been applied. This first coating 11 contains at least a proportion of an organic metal compound and/or a noble metal oxide. In this specific example, the first coating 11 contains Ag₂CO₃, Ag₂O and/or AgO. A second coating 12 which contains a fatty acid as reducing agent has been applied to the particles 10. Thus, the second coating 12 containing reducing agent directly adjoins the first coating 11 and encloses this, for example, completely. The proportion of fatty acid in the second coating 12 is selected so that the fatty acid is present in a stoichiometric ratio to the organic metal compound 11 composed of Ag₂CO₃, Ag₂O and/or AgO present in the particles 10 in the form of the first coating 11.

FIG. 1b schematically shows an alternative embodiment of particles of a starting material. Unlike the example in FIG. 1a, the particles 10′ are composed essentially entirely of Ag₂CO₃, Ag₂O and/or AgO.

A starting material according to the invention can optionally contain further particles in addition to the particles 10 corresponding to FIG. 1a and/or the particles 10′ corresponding to FIG. 1b.

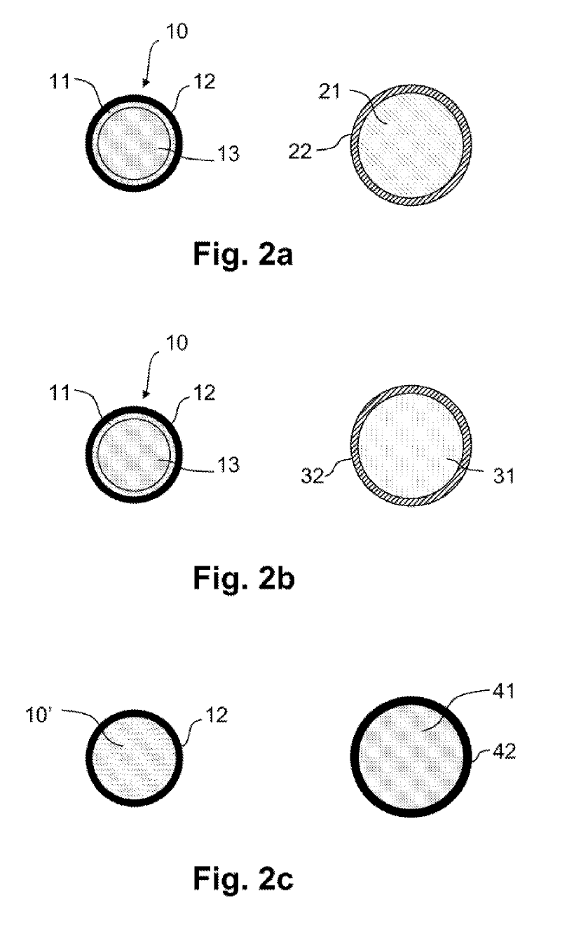

Thus, FIG. 2a shows by way of example a first mixture of particles which can be present in a starting material according to the invention. The first mixture has particles 10 corresponding to FIG. 1a and further particles 21 composed of silicon. The further particles 21 composed of silicon have an additional coating 22 composed of a silver compound.

FIG. 2b schematically shows a mixture which is an alternative to the first mixture of particles and in which further particles 31 which are composed of tin and have a coating 32 composed of a silver compound are provided instead of the further particles 21 composed of silicon.

FIG. 2c again schematically shows a further mixture of particles which is preferably provided in a starting material. Here, particles 10′ corresponding to FIG. 1b and additionally further particles 41 composed of silver are present as a mixture. Furthermore, an additional coating 42 composed of a fatty acid has been applied to the further particles 41 composed of silver.

The particles 10, 10′, 21, 31, 41 present in the starting material have a particle size of 0.1-10 μm. The particles 10, 10′ are preferably smaller than the further particles 21, 31, 41.

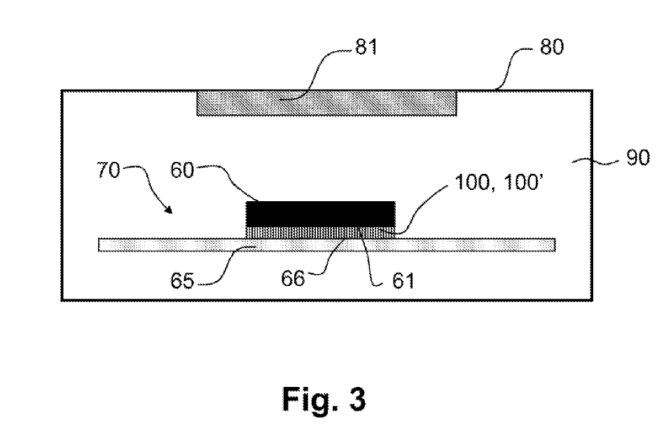

FIG. 3 shows a sintering oven 80 and also an electronic circuit 70 arranged in a process space 90 of the sintering oven 80. The electronic circuit 70 has a substrate 65 having at least a first contact point 66 composed of copper. A chip 60 having at least one second contact point 61 composed of a silver alloy is arranged on the substrate 65. Between the at least first contact point 66 composed of copper and the at least second contact point 61 composed of the silver alloy, a starting material 100 according to the invention has been applied as a paste. The starting material 100 contains a proportion of a mixture of particles 10, 21 or 10, 31 corresponding to FIGS. 2a and 2b.

To form a sintered bond 100′ between the at least first contact point 66 of the substrate 65 and the at least second contact point 61 of the chip 60, the electronic circuit 70 with the starting material 100 present therein is subjected to a thermal treatment. To carry out the thermal treatment, the sintering oven 80 contains a heating device within the process space 90. A vacuum or a protective gas atmosphere, for example, is present in the process space 90 during the thermal treatment of the starting material 100.

As a result of the thermal treatment of the electronic circuit 70, chemical reaction processes are triggered in the starting material 100. Thus, a reduction process is started by means of the fatty acid of the second coating 12 of the particles 10 present in the starting material 100. In this, the fatty acid 12 acts as a reducing agent which reduces the organic metal compound 11 composed of Ag₂CO₃, Ag₂O and/or AgO present within the first coating 11 of the particles 10 to elemental silver. This reduction occurs at a temperature below the sintering temperature of silver.

As a result of the stoichiometric ratio of the fatty acid of the second coating 12 to the proportion of organic metal compound composed of Ag₂O₃, Ag₂O or AgO present in the first coating 11 of the particles 10, the first coating 11 is largely completely converted into silver. In addition, virtually no residues of fatty acid remain in the sintered bond 100′ formed; otherwise, in the case of a residual amount of <1%, this residue would have to be burnt out with introduction of oxygen.

The metallic core 13 of the particles 10 sinters with the first coating 11 which is arranged on the core 13 and has been converted into silver and forms a silver matrix as part of the sintered microstructure of the sintered bond 100′ which forms. Likewise, contacting of the first and second contact points 61, 66 of the substrate and chip 65 is effected by means of the sintered bond 100′ formed. Contacting of the first contact point 66 composed of copper during the thermal treatment is possible without corrosion phenomena since contacting is carried out in vacuo or under a protective gas atmosphere. As a result, a non-noble material, for example composed of copper, also remains free of oxidation products during the thermal treatment to form the sintered bond 100′.

The further particles 31 composed of tin which are present as a mixture with the particles 10 in the starting material 100 melt at an early stage during the thermal treatment and aid intimate contact of all particles 10, 21, 31 present in the starting material 100. In addition, the tin of the further particles 31 forms alloys with the silver of the first coating 11 which has been transformed by the reduction. These alloys are then present as ductile phases within the silver matrix formed in the sintered microstructure.

The further particles 21 composed of silicon which are likewise present as a mixture in the starting material 100 are inert during the sintering process. Here, the coating 22 composed of the silver compound which has been applied to the further particles 21 aids sintering within the sintered microstructure. The further particles 21 composed of silicon are finely dispersed within the silver matrix of the sintered microstructure after formation of the sintered bond 100′.

1. A starting material (100) for a sintered bond (100′), which comprises particles (10, 10′) which contain at least a proportion of an organic metal compound and/or or a noble metal oxide, where the organic metal compound and/or the noble metal oxide are converted in a thermal treatment of the starting material (100) into the parent elemental metal and/or noble metal, characterized in that the particles (10, 10′) have a coating (12) containing a reducing agent by means of which the organic metal compound and/or the noble metal oxide are reduced to the elemental metal and/or noble metal at a temperature below the sintering temperature of the elemental metal and/or noble metal.

2. The starting material as claimed in claim 1, characterized in that the particles (10, 10′) consist of the organic metal compound and/or of the noble metal oxide.

3. The starting material as claimed in claim 1, characterized in that the particles (10, 10′) have a metallic core (13) and the organic metal compound and/or the noble metal oxide are/is applied as coating (11) to the metallic core (13).

4. The starting material as claimed in claim 3, characterized in that the metallic core (13) contains a noble metal.

5. The starting material as claimed in claim 3, characterized in that the metallic core (13) is composed of silver, gold, platinum, palladium and/or copper.

6. The starting material as claimed in claim 1, characterized in that the coating (12) containing a reducing agent comprises at least one organic material.

7. The starting material as claimed in claim 6, characterized in that the organic material is a fatty acid, or in that it is a mixture of various fatty acids.

8. The starting material as claimed in claim 1, characterized in that the organic metal compound is a silver carbonate, a silver lactate, a silver stearate or a sodium carbonate.

9. The starting material as claimed in claim 1, characterized in that the noble metal oxide is a silver oxide.

10. The starting material as claimed in claim 1, characterized in that the proportion of organic metal compound and/or noble metal oxide is in a stoichiometric ratio to the proportion of the reducing agent in the coating (12) containing a reducing agent.

11. The starting material as claimed in claim 1, characterized in that the particles (10, 10′) have an average particle size of 0.01-50 μm.

12. The starting material as claimed in claim 1, characterized in that further particles (21, 31, 41) containing a noble metal and/or an element of the fourth main group of the Periodic Table are additionally provided.

13. The starting material as claimed in claim 12, characterized in that the further particles (21, 31, 41) have a coating composed of a noble metal or an organic coating containing a reducing agent.

14. A sintered bond derived from a starting material as claimed in any of claims 1 to 13 claim 1, characterized in that the thermal conductivity of the sintered bond (100′) is >100 W/mK.

15. The sintered bond as claimed in claim 14, characterized in that the sintered bond (100′) contains at least a proportion of a silver-sodium alloy.

16. An electronic circuit (70) having a sintered bond (100′) as claimed in claim 14.

17. The electronic circuit (70) as claimed in claim 16, characterized in that the sintered bond (100′) has an electrical, thermal and/or mechanical contact point (61, 66) to at least one electrical or electronic component (60, 65).

18. A process for forming a thermally and/or electrically conductive sintered bond (100′), where a starting material (100) for the sintered bond (100′) as claimed in claim 1 is provided, which comprises the following steps:
provision of the starting material (100),
formation of the sintered bond (100′) by thermal treatment of the starting material (100), where the organic metal compound and/or the noble metal oxide are reduced to the elemental metal and/or noble metal by means of the coating (12) containing a reducing agent at a temperature below the sintering temperature of the elemental metal and/or noble metal.

19. The process as claimed in claim 18, characterized in that the sintered bond (100′) is formed at a temperature below 500° C.

20. The sintered bond as claimed in claim 18, characterized in that the sintered bond (100′) is formed under reduced pressure and/or in a nitrogen atmosphere.

21. The process as claimed in claim 18, characterized in that the starting material (100) is in the form of a printing paste for screen printing or stenciling, or for an ink jet application process, or in the form of a shaped part.

22. The starting material as claimed in claim 1, characterized in that the coating (12) containing a reducing agent comprises at least one alcohol selected from the group consisting of primary and secondary alcohols, and/or an amine and/or a formic acid.

23. The starting material as claimed in claim 6, characterized in that the organic material is an isostearic acid, a stearic acid, an oleic acid, or a lauric acid, or in that it is a mixture of various fatty acids.

24. The starting material as claimed in claim 1, characterized in that the particles (10, 10′) have an average particle size of 0.1-10 μm.

25. The process as claimed in claim 18, characterized in that the sintered bond (100′) is formed at a temperature below 250° C.

26. The process as claimed in claim 18, characterized in that the starting material (100) is in the form of a printing paste for screen printing or stenciling, or for an ink jet application process, or in the form of a shaped part.
